(19) United States
(12) Patent Application Publication
(10) Pub. No.: US 2017/0162255 A1
(43) Pub. Date: Jun. 8, 2017

(54) LOW RESISTANCE POWER HEADER WITH REDUCED INSTANTANEOUS VOLTAGE DROP

(71) Applicants: Jan-Michael HUBER, Cedar Park, TX (US); Michael BRAGANZA, San Francisco, CA (US)

(72) Inventors: Jan-Michael HUBER, Cedar Park, TX (US); Michael BRAGANZA, San Francisco, CA (US)

(21) Appl. No.: 15/096,273

(22) Filed: Apr. 11, 2016

Related U.S. Application Data
(60) Provisional application No. 62/262,166, filed on Dec. 2, 2015.

(51) Int. Cl. G11C 11/418; G11C 11/412; G11C 7/12; G11C 5/14; G11C 5/06

(52) U.S. Cl. CPC G11C 11/418; G11C 5/14; G11C 5/063; G11C 7/12; G11C 11/412

(57) ABSTRACT

A power header includes a first line, and a first power-enable control device that comprises a source region and a drain region. The drain region of the first power-enable control device is coupled to the first line through a silicon-only connection, and the source region of the first power-enable control device being coupled to a power supply. In one embodiment, the first line may be coupled to a logic circuit through a silicon-only connection. In another embodiment, the first line may be coupled to a buffer circuit through a silicon-only connection. In still another embodiment, the first line may be coupled to a static random access memory cell precharge circuit.

### CROSS-REFERENCE TO RELATED APPLICATION

This patent application claims the priority benefit under 35 U.S.C. §119(e) of U.S. Provisional Patent Application No. 62/262,166 filed on Dec. 2, 2015, the disclosure of which is incorporated herein by reference in its entirety.

### TECHNICAL FIELD

The present disclosure relates to semiconductor devices. More particularly, the present disclosure relates to a power header that provides a reduced Instantaneous Voltage Drop (IVD).

### BACKGROUND

Gated power supplies are essential for lowering circuit leakage when a given block or region within a static random access memory (SRAM) is not in use. Current flowing through a power network of a gated power supply produces an instantaneous voltage drop (IVD) that is experienced at the logic devices on the load side of the power header. The IVD is produced by current flowing through any resistance in the power network. An IVD is especially significant at a resistance that is associated with a silicon-to-metal (silicon-metal) interface. The IVD limits performance of a SRAM because the voltage experienced on the load side of the power header may be significantly less than the chip supply voltage. Additionally, silicon-metal interfaces inherently stresses the metal (and vias) due to electromigration, and lowers the current because the silicon-metal interface is relatively large.

In high-speed SRAM designs, precharge circuits present special challenges when gated power supplies are used. The bitlines of an SRAM are precharged simultaneously, which causes relatively high currents to flow through the precharge devices and produces large IVDs. Thus, large bit line capacitances combined with an IVD of a power header tend to limit the high-frequency performance of the SRAM. Moreover, the precharge devices tend to be all physically aligned, which causes a significant amount of current to be drawn from a relatively small portion of the power grid.

### SUMMARY

An embodiment provides a power header, comprising: a first conductive line; and a first power-enable control device comprising a source region and a drain region, the drain region of the first power-enable control device coupled to the first conductive line through a silicon-only connection, and the source region of the first power-enable control device being coupled to a power supply.

Another embodiment provides a power header, comprising: a first circuit comprising a first control device, the first control device comprising a source region and a drain region; and a first power-enable control device comprising a source region and a drain region, the drain region of the first power-enable control device being the source region of the first control device, and the source region of the first power-enable control device being coupled to a power supply. The first circuit may comprise at least one static random access memory cell precharge circuit, a logic circuit or a buffer circuit.

An embodiment provides a power header, comprising: a first line to be supplied with power; and a first power-enable control device comprising a source region and a drain region, the drain region of the first power-enable control device coupled to the first line through a silicon-only connection, and the source region of the first power-enable control device being coupled to a power supply. In one embodiment, the first line may be coupled to a logic circuit through a silicon-only connection. In another embodiment, the first line may be coupled to a buffer circuit through a silicon-only connection. In still another embodiment, the first line may be coupled to a static random access memory cell precharge circuit.

### BRIEF DESCRIPTION OF THE DRAWINGS

In the following section, the aspects of the subject matter disclosed herein will be described with reference to exemplary embodiments illustrated in the figures, in which:

FIG. 1A depicts a typical configuration of a conventional power header/bit line precharge circuit for a static random access memory (SRAM);

FIG. 1B depicts an equivalent circuit diagram for the typical configuration of the conventional power header-bit line pre-charge circuit shown in FIG. 1A;

FIG. 2A depicts an example embodiment of a power header/bit line precharge circuit for an SRAM according to the subject matter disclosed herein;

FIG. 2B depicts an equivalent circuit diagram for the example embodiment of a power header/bit line precharge circuit shown in FIG. 2A according to the subject matter disclosed herein;

FIG. 2C depicts an example embodiment of a power header for a typical logic gate circuit according to the subject matter disclosed herein;

FIG. 2D depicts an example embodiment of a power header to a buffer circuit according to the subject matter disclosed herein;

FIG. 3 depicts an example timing diagram for the power enable and precharge control signals for the circuit shown in FIG. 2A;

FIG. 4A depicts a plan view of one example embodiment of a physical circuit layout of a power header/bit line precharge circuit for an SRAM according to the subject matter disclosed herein;

FIG. 4B depicts a cross-sectional view of the example embodiment of the physical layout of the power header/bit line precharge circuit for an SRAM according to the subject matter disclosed herein taken along line A-A′ in FIG. 4A;

FIG. 5 is a flow diagram for forming a power header/bit line precharge circuit for an SRAM according to the subject matter disclosed herein;

FIG. 6 depicts an electronic device that comprises one or more integrated circuits (chips) comprising at least one power header that is connected directly to a precharge transistor through silicon, thereby eliminating silicon-metal interfaces between a power header and a precharge transistor according to embodiments disclosed herein; and

FIG. 7 depicts a memory system that may comprise one or more integrated circuits (chips) comprising at least one power header that is connected directly to a precharge transistor through silicon, thereby eliminating silicon-metal interfaces between a power header and a precharge transistor according to embodiments disclosed herein.

### DETAILED DESCRIPTION

The subject matter disclosed herein relates to a power header that provides a reduced IVD.

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail not to obscure the subject matter disclosed herein.

Reference throughout this specification to “one embodiment” or “an embodiment” means that a particular feature, structure, or characteristic described in connection with the embodiment is included in at least one embodiment disclosed herein. Thus, the appearances of the phrases “in one embodiment” or “in an embodiment” or “according to one embodiment” (or other phrases having similar import) in various places throughout this specification are not necessarily all referring to the same embodiment. As used herein, the word “exemplary” means “serving as an example, instance, or illustration.” Any embodiment described herein as “exemplary” is not to be construed as necessarily preferred or advantageous over other embodiments. Furthermore, the particular features, structures, or characteristics may be combined in any suitable manner in one or more embodiments. Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. Similarly, various waveforms and timing diagrams are shown for illustrative purpose only.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement the teachings of particular embodiments disclosed herein.

Conventional power headers are useful for controlling power to blocks or regions of semiconductor circuits; however, the conventional configuration of power headers adds resistance to the local power supplies when the power headers are conducting. In many cases, a majority of the resistance associated with a conventional power header is related to silicon-metal interfaces within the power header structure. Such a conventional power header configuration includes three such silicon-metal interfaces. That is, a typical conventional power header configuration includes a silicon-metal interface on an input side of the power header, a silicon-metal interface on the output side of the power header, and a silicon-metal interface on the input side of the logic device. Morever, as semiconductor technologies scale smaller, the geometries of semiconductor devices become correspondingly smaller, thereby causing cross-sectional resistances of semiconductor devices to increase. Also, as transistor performance increases, currents correspondingly increase. The combined increases in current and resistance result in an increased IVD that is produced by the silicon-metal interfaces within a conventional power header configuration.

Embodiments disclosed herein reduce the IVD produced by power headers and experienced by devices on the load side of the power headers. Embodiments disclosed herein provide that power headers are connected directly to precharge transistors through silicon, thereby eliminating silicon-metal interfaces between a power header and a precharge transistor. That is, no metal is used to make a connection between a power header transistor and a precharge transistor so that there is no silicon-metal interface between a power header transistor and a precharge transistor. Moreover, because embodiments disclosed herein eliminate the metal from between a power header and an intended logic device, electromigration issues are similarly eliminated. Embodiments disclosed herien provide that each precharge device is arranged, or paired, with a corresponding local power header that is placed in the same diffusion region, thereby significantly reducing the series resistance in a power header to precharge transistor path. Thus, embodiments disclosed herein provide a significantly reduced IVD at precharge transistors, thereby improving SRAM performance and limiting issues relating to electromigration at silicon-metal interfaces. Embodiments disclosed herein are not limited to power header—precharge transistor configurations for SRAM devices and could be used to reduce IVD for, for example, large drivers, repeaters, clock drivers and large logic gates.

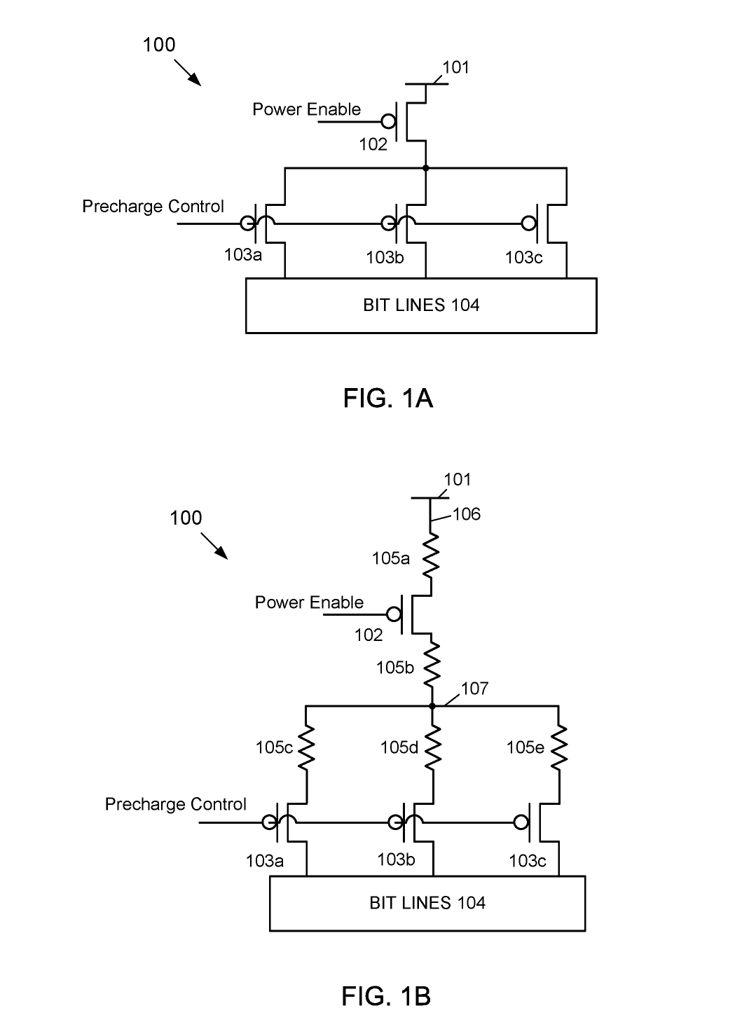

FIG. 1A depicts a typical configuration of a conventional power header/bit line precharge circuit 100 for a static random access memory (SRAM). As shown in FIG. 1A, a chip supply 101 is connected to a plurality of bit lines 104 through a power-enable transistor 102 and a plurality of precharge enable transistors 103a-103c. It should be understood that although only three precharge enable transistors 103 are shown in FIG. 1A, fewer or more precharge enable transistors 103 could be used depending on the number of bit lines 104 that are present. It should also be understood that although details of bit lines 104 are not shown, each respective bit line of the bit lines 104 is coupled to one or more SRAM memory cells (not shown) in a well-known manner.

A precharge control signal is coupled to the gate of each of the precharge transistors 103a-103c to control precharging of the bit lines 104. A power enable signal is coupled the gate of the power-enable transistor 102 to enable the application of power to the precharge transistors 103a-103c and the bit lines 104.

An interconnection node (node 106 in FIG. 1B) between the chip supply 101 and the power-enable transistor 102 includes a silicon-to-metal (silicon-metal) interface. Similarly, an interconnection node (node 107 in FIG. 1B) between the power-enable transistor 102 and the precharge enable transistors 103 include silicon-metal interfaces. The resistances associated with the silicon-metal interfaces adversely impact performance of circuit 100 by producing a relatively large Instantaneous Voltage Drop (IVD) as current passes from the chip supply 101 to the bit lines 104.

FIG. 1B depicts an equivalent circuit diagram for the typical configuration of the conventional power header-bit line pre-charge circuit 100 shown in FIG. 1A. FIG. 1B includes the resistances associated with the respective silicon-metal interfaces of circuit 100. It should be understood that the power header-bit line pre-charge circuit 100 may include other resistances that are not shown in FIG. 1B. In particular, each of the resistances 105a-105e in FIG. 1B represent a silicon-metal interface resistance because each of resistances 105a-105e may be significant in comparison to all other resistances that may exist in the power header-bit line pre-charge circuit 100. For example, resistance 105a is formed where a metallization 106 interfaces with silicon at a source of the power-enable transistor 102. Similarly, resistance 105b includes resistance from the interface between the drain of the power-enable transistor 102 interfaces with a metallization 107. Resistances 105c-105e are respectively formed where the metallization 107 interfaces with each of the sources of the precharge enable transistors 103a-103c. Thus, the load side of each of the precharge enable transistors 103a-103c for the conventional circuit 100 experiences an IVD produced by three silicon-metal interfaces.

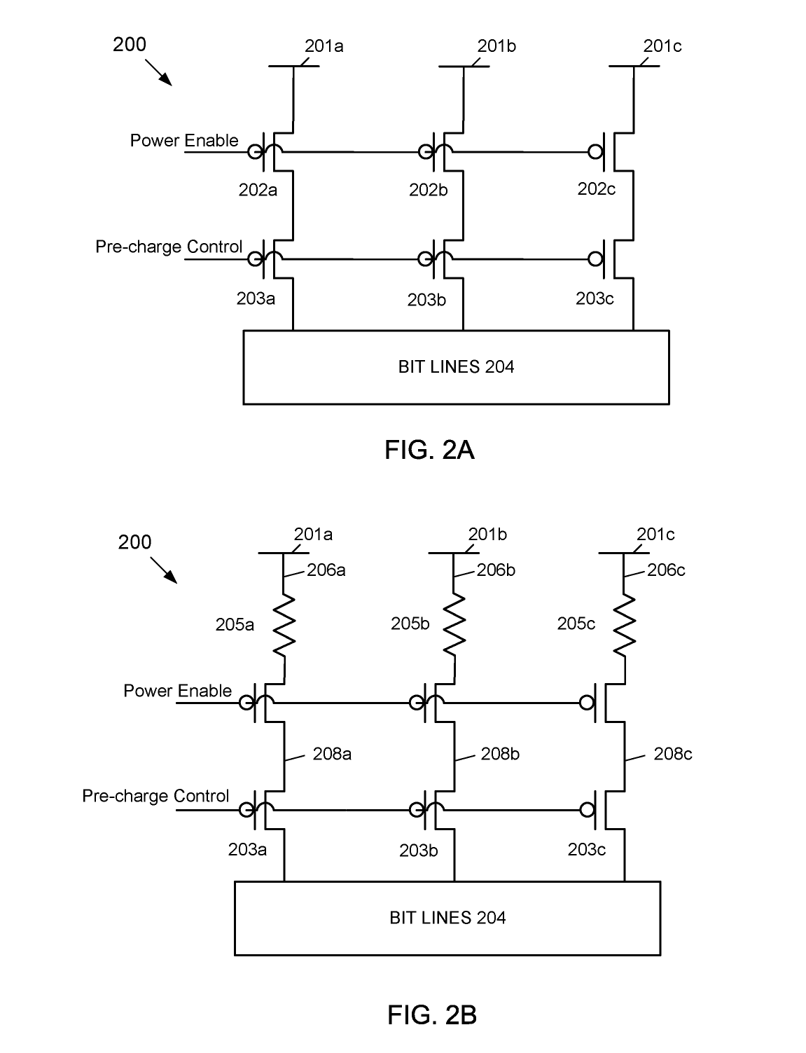

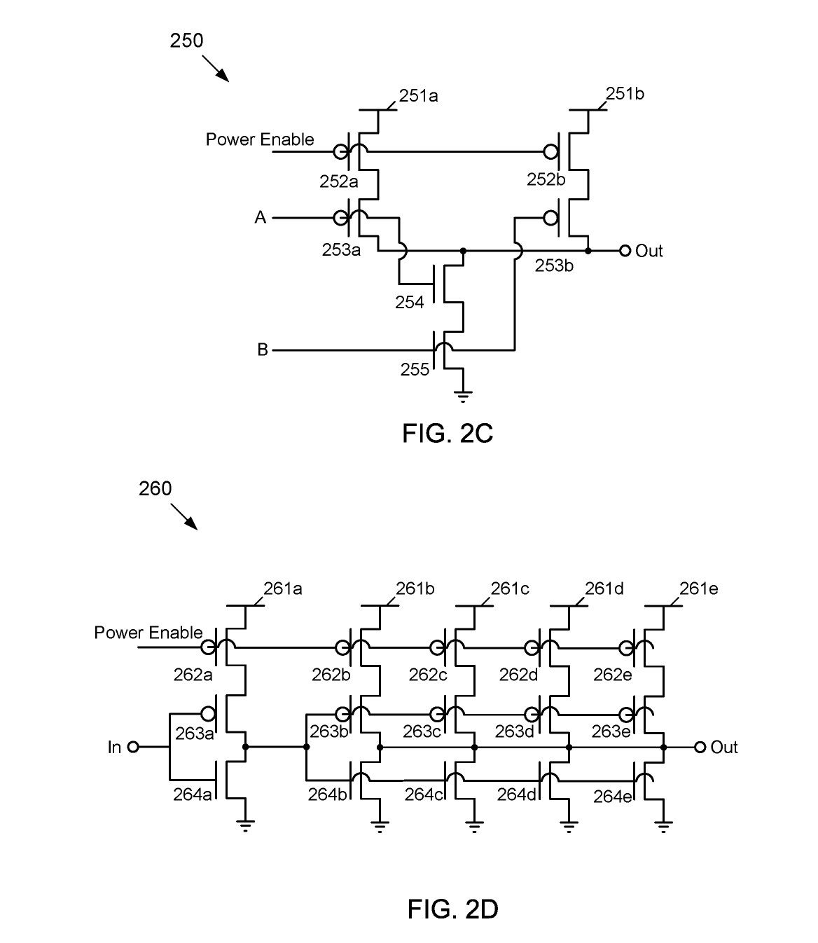

FIG. 2A depicts an example embodiment of a power header/bit line precharge circuit 200 for an SRAM according to the subject matter disclosed herein. As shown in FIG. 2A, chip supplies 201a-201c are connected to a plurality of bit lines 204 through a plurality of power-enable transistors 202a-202c and a plurality of precharge enable transistors 203a-203c. It should be understood that although only three precharge enable transistors 203 are shown in FIG. 2A, fewer or more precharge enable transistors 203 could be used depending on the number of bit lines 204 that are present. It should also be understood that although details of bit lines 204 are not shown, each respective bit line of bit lines 204 is coupled to one or more SRAM memory cells (not shown) in a well-known manner.

A precharge control signal is coupled to the gate of each of the pre-charge transistors 203a-203c to control precharging of the bit lines 204. A power enable signal is coupled to each of the gates of the power-enable transistors 202a-202c to enable the application of power to the precharge transistors 203a-203c and the bit lines 204.

For the embodiment shown in FIG. 2A, only the interconnection node (nodes 206a-206c in FIG. 2B) between a chip supply 201 and a power-enable transistor 202 includes a silicon-metal interface. Each interconnection node (nodes 208a-208c in FIG. 2B) between a power-enable transistor 202 and a precharge enable transistors 203 does not include a silicon-metal interface. That is, each respective interconnection node 208a-208c is a silicon-only interconnection.

FIG. 2B depicts an equivalent circuit diagram for the example embodiment of a power header/bit line precharge circuit 200 shown in FIG. 2A according to the subject matter disclosed herein. The equivalent circuit of FIG. 2B includes the resistances associated with the respective silicon-metal interfaces of circuit 200. In particular, each of the resistances 205a-205c shown in FIG. 2B represent a resistance associated with a silicon-metal interface the chip supply 201 and a source of power-enable transistor 202. In contrast to the conventional circuit 100 shown in FIGS. 1A and 1B, the load side of each of precharge enable transistors 203a-203c experiences an IVD produced by only one silicon-metal interface instead of an IVD produced by three silicon-metal interfaces.

FIG. 2C depicts an example embodiment of a power header 250 for a representative logic gate circuit according to the subject matter disclosed herein. As shown in FIG. 2C, chip supplies 251a-251b are connected to a plurality of power-enable transistors 252a-252b. In particular, a NAND logic circuit is formed by transistors 253a, 253b, 254 and 255. A power enable signal is coupled to the gate of each of the power-enable transistors 252a-252b to control power being applied to the representative logic gate circuit. It should be understood that other logic gate circuits could be used in place of the representative logic gate circuit depicted in FIG. 2C. For the embodiment shown in FIG. 2C, only the interconnection node between a chip supply 251 and a power-enable transistor 252 includes a silicon-metal interface. Each interconnection node between a power-enable transistor 252 and a transistor of the representative logic gate circuit does not include a silicon-metal interface. That is, each respective interconnection node between a power-enable transistor 252 and a transistor of the representative logic gate circuit is a silicon-only interconnection.

FIG. 2D depicts an example embodiment of a power header 260 to a driver circuit, or a buffer circuit, according to the subject matter disclosed herein. As shown in FIG. 2D, chip supplies 261a-261e are connected to a plurality of power-enable transistors 262a-262e. The driver circuit is formed by transistors 263a-263e and 264a-264e. A power enable signal is coupled to the gate of each of the power-enable transistors 262a-262e to control power being applied to the representative logic gate circuit. It should be understood that other buffer circuits could be used in place of the buffer circuit depicted in FIG. 2D. For the embodiment shown in FIG. 2D, only the interconnection node between a chip supply 261 and a power-enable transistor 262 includes a silicon-metal interface. Each interconnection node between a power-enable transistor 262 and a transistor of the driver circuit does not include a silicon-metal interface. That is, each respective interconnection node between a power-enable transistor 262 and a transistor of the driver circuit is a silicon-only interconnection.

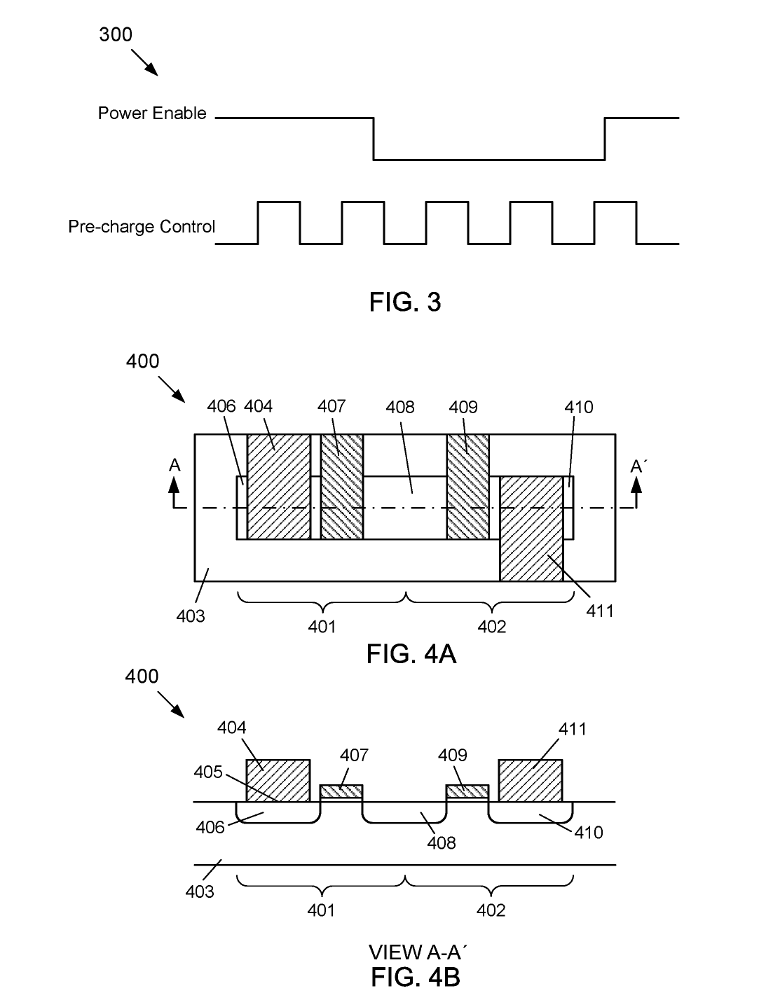

FIG. 3 depicts an example timing diagram 300 for the power enable and precharge control signals for the circuit 200 shown in FIG. 2A. As shown in diagram 300, the precharge control signal may operate as a clock-type signal in which a low-level actively turns the precharge transistors 203a-203c on, that is, causes the precharge transistors 203a-203c to conduct. The power enable signal is an active low signal and enables power to be applied to the precharge transistors 203a-203c and the bit lines 204 when the power enable signal is low. It should be understood that the timing diagram 300 depicts a general relationship between the power enable signal and the pre-charge control signal. Other timing scenarios are also possible. It should also be understood that the power-enable transistors and the precharge transistors could alternatively be configured to be active-high devices.

FIG. 4A depicts a plan view of one example embodiment of a physical circuit layout 400 of a power header/bit line precharge circuit for an SRAM according to the subject matter disclosed herein. FIG. 4B depicts a cross-sectional view of the example embodiment of the physical layout 400 of the power header/bit line precharge circuit for an SRAM according to the subject matter disclosed herein taken along line A-A′ in FIG. 4A. As depicted in FIGS. 4A and 4B, a power-enable transistor 401 and a corresponding precharge transistor 402 are formed in an active region of a substrate 403. It should be understood that layers, such as, but not limited to, an interlayer dielectric layer, are not shown in FIGS. 4A and 4B for clarity. Additionally, the various layers that are depicted in FIGS. 4A and 4B are formed using well-known techniques using well-known materials.

Referring to FIGS. 2A, 4A and 4B, and by way of example, the power-enable transistor 401 of FIGS. 4A and 4B corresponds to the power-enable transistor 202a in FIG. 2A, and the precharge transistor 402 corresponds to the precharge transistor 203a in FIG. 2A. A metallization 404 corresponds to metallization 206a in FIG. 2B. A silicon-metal interface 405 corresponds to the silicon-metal interface resistance 205a. A drain/source region 406 corresponds to the source of the power-enable transistor 202a. A gate structure 407 corresponds to the gate of the power-enable transistor 202a. A drain/source region 408 corresponds to the drain of the power-enable transistor 202a and the source of the precharge transistor 203a. A gate structure 409 corresponds to the gate of the precharge transistor 203a. A drain/source region 410 corresponds to the drain of precharge transistor 203a. A metallization 411 corresponds to or is connected to a bit line 204.

As can be seen in FIGS. 4A and 4B, no metal is used to make a connection between the power header transistor 401 and the precharge transistor 402. That is, the power-enable transistor 401 and the precharge transistor 402 share the drain/source region 408. As a result, there is no silicon-metal interface resistance between the power-enable transistor 401 and the precharge transistor 402.

Although the subject matter disclosed herein has been described in terms of a precharge transistor being coupled to a bit line, it should be understood that the subject matter disclosed herein is applicable to all circuits in which a precharge-type transistor is coupled to a line that in operation is precharged to reduce IVD experienced by a load, such as, but not limited to, large drivers, repeaters, clock drivers and large logic gates.

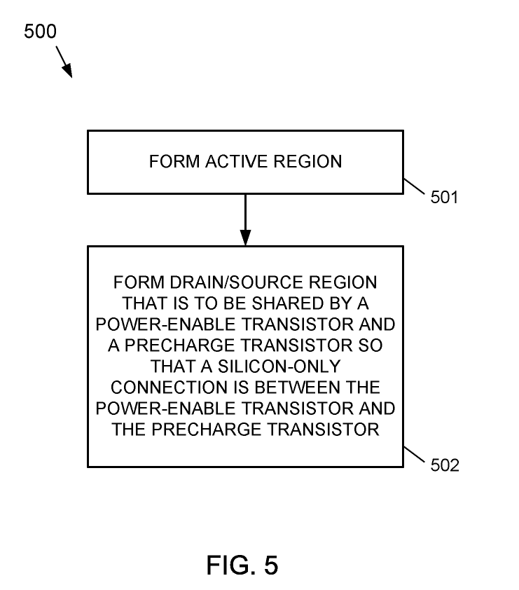

FIG. 5 is a flow diagram 500 for forming a power header/bit line precharge circuit for an SRAM according to the subject matter disclosed herein. At operation 501, an active region is formed in a silicon substrate using well-known techniques and well-known materials. At operation 502, a drain/source region is formed in the active region using well-known techniques and well-known materials. The drain/source region that is formed in operation 502 is to be shared by a power-enable transistor of a power header and a precharge transistor so that a silicon-only connection is formed between the power-enable transistor and the precharge transistor. Additional well-known operations may be performed to add structures as gate structures and metalization to complete the power-enable transistor and the precharge transistor. It should be understood that although the flow diagram 500 describes a process for forming only one drain/source region for a pair of power-control and precharge transistors, more than one drain/source regions may be formed for corresponding pairs of power-control and precharge transistors.

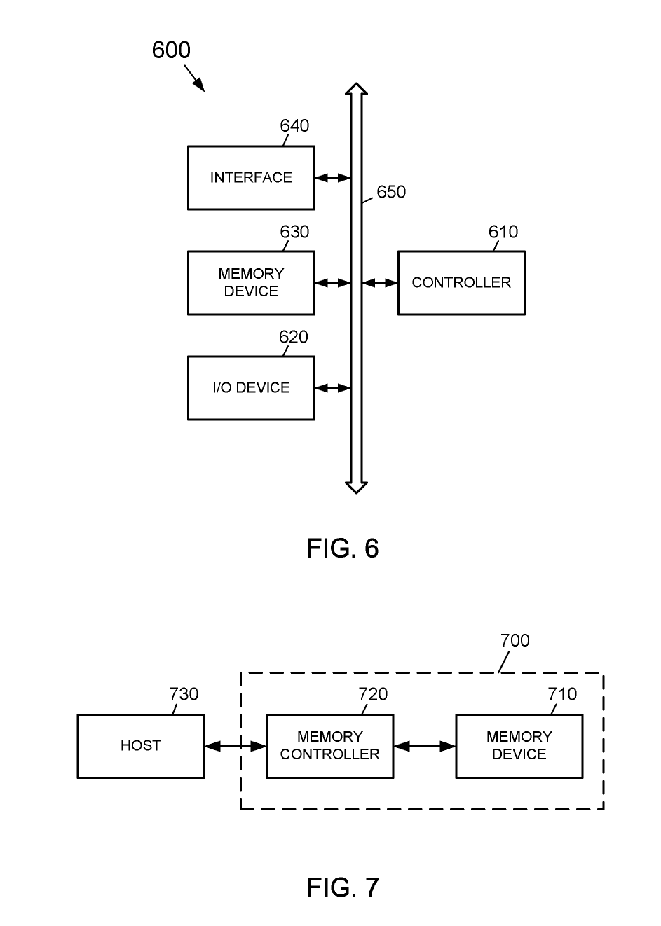

FIG. 6 depicts an electronic device 600 that comprises one or more integrated circuits (chips) comprising at least one power header that is connected directly to a precharge transistor through silicon, thereby eliminating silicon-metal interfaces between a power header and a precharge transistor according to embodiments disclosed herein. Electronic device 600 may be used in, but not limited to, a computing device, a personal digital assistant (PDA), a laptop computer, a mobile computer, a web tablet, a wireless phone, a cell phone, a smart phone, a digital music player, or a wireline or wireless electronic device. The electronic device 600 may comprise a controller 610, an input/output device 620 such as, but not limited to, a keypad, a keyboard, a display, or a touch-screen display, a memory 630, and a wireless interface 640 that are coupled to each other through a bus 650. The controller 610 may comprise, for example, at least one microprocessor, at least one digital signal process, at least one microcontroller, or the like. The memory 630 may be configured to store a command code to be used by the controller 610 or a user data. Electronic device 600 and the various system components comprising electronic device 600 may comprise at least one power header that is connected directly to a precharge transistor through silicon, thereby eliminating silicon-metal interfaces between a power header and a precharge transistor according to embodiments disclosed herein. The electronic device 600 may use a wireless interface 640 configured to transmit data to or receive data from a wireless communication network using a RF signal. The wireless interface 640 may include, for example, an antenna, a wireless transceiver and so on. The electronic system 600 may be used in a communication interface protocol of a communication system, such as, but not limited to, Code Division Multiple Access (CDMA), Global System for Mobile Communications (GSM), North American Digital Communications (NADC), Extended Time Division Multiple Access (E-TDMA), Wideband CDMA (WCDMA), CDMA2000, Wi-Fi, Municipal Wi-Fi (Muni Wi-Fi), Bluetooth, Digital Enhanced Cordless Telecommunications (DECT), Wireless Universal Serial Bus (Wireless USB), Fast low-latency access with seamless handoff Orthogonal Frequency Division Multiplexing (Flash-OFDM), IEEE 802.20, General Packet Radio Service (GPRS), iBurst, Wireless Broadband (WiBro), WiMAX, WiMAX-Advanced, Universal Mobile Telecommunication Service-Time Division Duplex (UMTS-TDD), High Speed Packet Access (HSPA), Evolution Data Optimized (EVDO), Long Term Evolution-Advanced (LTE-Advanced), Multichannel Multipoint Distribution Service (MMDS), and so forth.

FIG. 7 depicts a memory system 700 that may comprise one or more integrated circuits (chips) comprising at least one power header that is connected directly to a precharge transistor through silicon, thereby eliminating silicon-metal interfaces between a power header and a precharge transistor according to embodiments disclosed herein. The memory system 700 may comprise a memory device 710 for storing large amounts of data and a memory controller 720. The memory controller 720 controls the memory device 710 to read data stored in the memory device 710 or to write data into the memory device 710 in response to a read/write request of a host 730. The memory controller 730 may include an address-mapping table for mapping an address provided from the host 730 (e.g., a mobile device or a computer system) into a physical address of the memory device 710. The memory device 710 may comprise one or more semiconductor devices comprising at least one power header that is connected directly to a precharge transistor through silicon, thereby eliminating silicon-metal interfaces between a power header and a precharge transistor according to embodiments disclosed herein.

As will be recognized by those skilled in the art, the innovative concepts described herein can be modified and varied over a wide range of applications. Accordingly, the scope of claimed subject matter should not be limited to any of the specific exemplary teachings discussed above, but is instead defined by the following claims.

1. A power header, comprising:
a first conductive line; and
a first power-enable control device comprising a source region and a drain region, the drain region of the first power-enable control device coupled to the first conductive line through a silicon-only connection, and the source region of the first power-enable control device being coupled to a power supply.

2. The power header according to claim 1, wherein the first conductive line comprises a first bit line coupled to at least one first static random access memory cell,
the power header further comprising a first precharge control device comprising a source region and a drain region, the drain region of the first precharge control device being coupled to the first bit line,
wherein the drain region of the first power-enable control device is coupled to the source region of the first precharge control device through a silicon-only connection through the first conductive line.

3. The power header according to claim 2, wherein the first precharge control device further comprises a control terminal and a channel between the source region and the drain region of the first precharge control device, the control terminal of the first precharge control device to receive a first control signal to control a conduction through the channel between the source region and the drain region of the first precharge control device, and
wherein the first power-enable control device further comprises a control terminal and a channel between the source region and the drain region of the first power-enable control device, the control terminal of the first power-enable control device to receive a second control signal to control a conduction through the channel between the source region and the drain region of the first power-enable control device.

4. The power header according to claim 2, further comprising:
a second bit line coupled to at least one second static random access memory cell;
a second precharge control device coupled to the second bit line, the second precharge control device comprising a source region and a drain region, the drain region of the second precharge control device being coupled to the second bit line; and
a second power-enable control device comprising a source region and a drain region, the drain region of the second power-enable control device being the drain region of the second precharge control device, and the source region of the second power-enable control device being coupled to the power supply.

5. The power header according to claim 4, wherein the second precharge control device further comprises a control terminal and a channel between the source region and the drain region of the second precharge control device, the control terminal of the second precharge control device to receive a third control signal to control a conduction through the channel between the source region and the drain region of the second precharge control device, and
wherein the second power-enable control device further comprises a control terminal and a channel between the source region and the drain region of the second power-enable control device, the control terminal of the second power-enable control device to receive a fourth control signal to control a conduction through the channel between the source region and the drain region of the second power-enable control device.

6. The power header according to claim 1, further comprising a logic circuit, the logic circuit comprising a first control device comprising a source region and a drain region, the source region of the first control device being coupled to the drain region of the first power-enable control device through a silicon-only connection.

7. The power header according to claim 1, further comprising a driver circuit, the driver circuit comprising a first control device comprising a source region and a drain region, the source region of the first control device being coupled to the drain region of the first power-enable control device through a silicon-only connection.

8. A power header, comprising:
a first circuit comprising a first control device, the first control device comprising a source region and a drain region; and
a first power-enable control device comprising a source region and a drain region, the drain region of the first power-enable control device being the source region of the first control device, and the source region of the first power-enable control device being coupled to a power supply.

9. The power header according to claim 8, wherein the first circuit comprises a logic circuit or a buffer circuit.

10. The power header according to claim 8, wherein the first circuit comprises at least one static random access memory cell and a conductive line coupled to the at least one static random access memory cell,
wherein the first control device comprises a first precharge control device, the first precharge control device comprising a control terminal and a channel between the source region and the drain region of the first precharge control device, the control terminal of the first precharge control device to receive a first control signal to control a conduction through the channel between the source region and the drain region of the first precharge control device, and
wherein the first power-enable control device further comprises a control terminal and a channel between the source region and the drain region of the first power-enable control device, the control terminal of the first power-enable control device to receive a second control signal to control a conduction through the channel between the source region and the drain region of the first power-enable control device.

11. The power header according to claim 10, wherein the first conductive line is a first bit line.

12. The power header according to claim 11, further comprising:
a second conductive line to be charged;
a second precharge control device coupled to the second conductive line, the second precharge control device comprising a source region and a drain region, the drain region of the second precharge control device being coupled to the second conductive line; and
a second power-enable control device comprising a source region and a drain region, the drain region of the second power-enable control device being the source region of the second precharge control device, and the drain region of the second power-enable control device being coupled to the power supply.

13. The power header according to claim 12, wherein the second precharge control device further comprises a control terminal and a channel between the drain region and the source region of the second precharge control device, the control terminal of the second precharge control device to receive a third control signal to control a conduction through the channel between the source region and the drain region of the second precharge control device.

14. The power header according to claim 13, wherein the second power-enable control device further comprises a control terminal and a channel between the source region and the drain region of the second power-enable control device, the control terminal of the second power-enable control device to receive a fourth control signal to control a conduction through the channel between the source region and the drain region of the second power-enable control device.

15. The power header according to claim 12, wherein the second conductive line is a second bit line, and
wherein the second bit line is coupled to at least one second static random access memory cell.

16. A power header, comprising:
a first line to be supplied with power; and
a first power-enable control device comprising a source region and a drain region, the drain region of the first power-enable control device coupled to the first line through a silicon-only connection, and the source region of the first power-enable control device being coupled to a power supply.

17. The power header according to claim 16, wherein the first line is coupled to a logic circuit through a silicon-only connection.

18. The power header according to claim 16, wherein the first line is coupled to a buffer circuit through a silicon-only connection.

19. The power header according to claim 16, wherein the first line comprises a first bit line,
the power header further comprising a precharge control transistor, the precharge control transistor comprising a source region and a drain region, and the drain region of the precharge control transistor being coupled to the first bit line, and the power-enable transistor comprising a source region and a drain region, the drain region of the power-enable transistor being the source region of the precharge control transistor, and the source region of the power-enable transistor being coupled to a power supply.

20. The power header according to claim 19, wherein the precharge control transistor further comprises a control terminal and a channel between the source region and the drain region of the precharge control transistor, the control terminal of the precharge control transistor to receive a first control signal to control a conduction through the channel between the source region and the drain region of the precharge control transistor, and
wherein the power-enable transistor further comprises a control terminal and a channel between the source region and the drain region of the power-enable transistor, the control terminal of the power-enable transistor to receive a second control signal to control a conduction through the channel between the source region and the drain region of the power-enable transistor.
